(19) United States
(12) Patent Application Publication
(10) Pub. No.: US 2012/0085575 A1
(43) Pub. Date: Apr. 12, 2012

(54) Electronic Apparatus Manufacturing Method, Electronic Component, and Electronic Apparatus

(76) Inventors: Nobuhiro Yamamoto, Fussa-shi (JP); Takahisa Funayama, Musashino-shi (JP)

(21) Appl. No.: 13/093,641

(22) Filed: Apr. 25, 2011

(30) Foreign Application Priority Data
Oct. 8, 2010 (JP) 2010-228779

(51) Int. Cl. H05K 1/11; H05K 3/34

(52) U.S. Cl. 174/267; 29/840

(57) ABSTRACT

According to one embodiment, a manufacturing method for an electronic apparatus, which includes a housing, a substrate, pads on the substrate, and an electronic component, which includes a component body including a bottom surface, terminals arranged on the bottom surface of the component body, and a thermosetting resin disposed on the bottom surface of the component body and configured to remove an oxide film when heated, and is mounted on the substrate, the method includes putting the electronic component on the substrate, heating the electronic component, thereby softening the resin, causing the softened resin to flow, thereby forcing out a gas between the electronic component and the substrate and filling the resin between the electronic component and the substrate, and further heating the electronic component, thereby solder-bonding the terminals and the pads to one another and curing the resin between the electronic component and the substrate.

### CROSS-REFERENCE TO RELATED APPLICATIONS

This application is based upon and claims the benefit of priority from Japanese Patent Application No. 2010-228779, filed Oct. 8, 2010; the entire contents of which are incorporated herein by reference.

### FIELD

Embodiments described herein relate generally to an electronic apparatus manufacturing method, an electronic component, and an electronic apparatus.

### BACKGROUND

In an electronic apparatus, such as a portable computer, a BGA and other bottom-surface electrode components are mounted on a printed circuit board. In order to prevent the electrode components from coming off the circuit board, a reinforcement resin is introduced between the electrode component and circuit board.

For example, a thermosetting resin is introduced along the bottom-surface electrode component on the printed circuit board. The resin is softened and caused to penetrate into a gap between the electrode component and circuit board by a capillary phenomenon. As this resin is thermally cured, the connection between the electrode component and circuit board is reinforced.

In some cases, a resin may be previously applied to the bottom-surface electrode component. In mounting this electrode component, solder-bonding and the filling and thermal curing of the resin can be performed in one process.

If the bottom-surface electrode component is heated for solder-bonding or resin curing, a gas such as water vapor is produced by the resin or solder. If the gas remains between the electrode component and printed circuit board, it causes air bubbles to be formed within the thermally cured resin. These air bubbles may loosen the connection between the electrode component and circuit board.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary cutaway perspective view showing a portable computer according to a first embodiment;

FIG. 2 is an exemplary sectional view showing a substrate and BGA of the first embodiment;

FIG. 3 is an exemplary sectional view showing the BGA of the first embodiment to be mounted;

FIG. 4 is an exemplary plan view of the BGA of the first embodiment taken in the direction of arrow F4 of FIG. 3;

FIG. 5 is an exemplary sectional view schematically showing how the BGA of the first embodiment is put on the substrate;

FIG. 6 is an exemplary sectional view schematically showing how a resin of the first embodiment flows;

FIG. 7 is an exemplary sectional view schematically showing how the BGA of the first embodiment is pressed against the substrate;

FIG. 8 is an exemplary sectional view showing a BGA according to a second embodiment to be mounted;

FIG. 9 is an exemplary plan view of the BGA of the second embodiment taken in the direction of arrow F9 of FIG. 8;

FIG. 10 is an exemplary sectional view showing a BGA according to a third embodiment to be mounted;

FIG. 11 is an exemplary plan view of the BGA of the third embodiment taken in the direction of arrow F11 of FIG. 10;

FIG. 12 is an exemplary sectional view showing a BGA according to a fourth embodiment to be mounted;

FIG. 13 is an exemplary plan view of the BGA of the fourth embodiment taken in the direction of arrow F13 of FIG. 12;

FIG. 14 is an exemplary plan view showing a BGA according to a fifth embodiment to be mounted;

FIG. 15 is an exemplary sectional view showing a BGA according to a sixth embodiment to be mounted;

FIG. 16 is an exemplary sectional view showing a BGA according to a seventh embodiment to be mounted;

FIG. 17 is an exemplary plan view showing a BGA according to an eighth embodiment to be mounted; and

FIG. 18 is an exemplary sectional view schematically showing how a BGA according to a ninth embodiment is put on the substrate.

### DETAILED DESCRIPTION

Various embodiments will be described hereinafter with reference to the accompanying drawings.

In general, according to one embodiment, a manufacturing method for an electronic apparatus, which includes a housing, a substrate, pads on the substrate, and an electronic component, which includes a component body including a bottom surface, terminals arranged on the bottom surface of the component body, and a thermosetting resin disposed on the bottom surface of the component body and configured to remove an oxide film when heated, and is mounted on the substrate, the method includes: putting the electronic component on the substrate; heating the electronic component, thereby softening the resin; causing the softened resin to flow, thereby forcing out a gas between the electronic component and the substrate and filling the resin between the electronic component and the substrate; and further heating the electronic component, thereby solder-bonding the terminals and the pads to one another and curing the resin between the electronic component and the substrate.

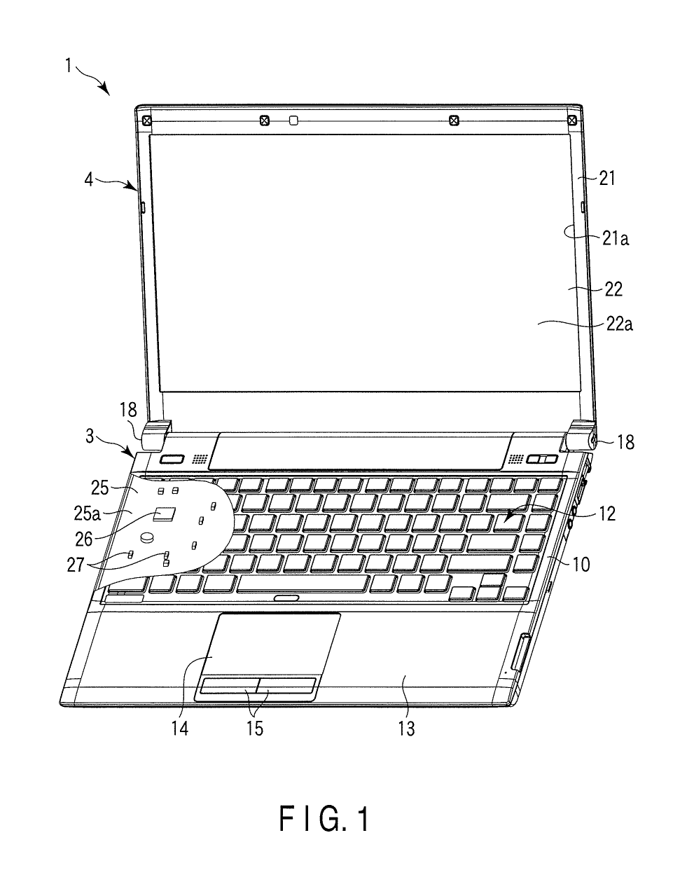

A first embodiment will now be described with reference to FIGS. 1 to 7. In this specification, the user side is defined as forward; the far side from the user as rearward, the user's left-hand side as leftward, the user's right-hand side as rightward, the upper side with respect to the user as upward, and the lower side with respect to the user as downward.

FIG. 1 is an exemplary cutaway perspective view of a portable computer 1. The portable computer 1 is an example of the electronic apparatus. As shown in FIG. 1, the computer 1 comprises a main unit 3 and display unit 4.

The main unit 3 comprises a flat box-like housing 10. A keyboard 12, palmrest 13, touchpad 14, and a pair of buttons 15 are arranged on the upper surface of the housing 10.

The display unit 4 is connected to the rear end of the main unit 3 by a pair of hinges 18. The hinges 18 are individually arranged at the lower end of the display unit 4.

The display unit 4 is pivotable about the hinges 18 between closed and open positions. In the closed position, the display unit 4 lies on the main unit 3. In the open position, the display unit 4 rises from the rear end of the main unit 3.

The display unit 4 comprises a flat box-like display housing 21 and display module 22. The display module 22 is, for example, a liquid crystal display accommodated in the display housing 21.

A display aperture 21a is formed in the front surface of the display housing 21. A screen 22a of the display module 22 is exposed to the outside of the display unit 4 through the display aperture 21a.

As shown in FIG. 1, the main unit 3 comprises a substrate 25, BGA 26, and a plurality of electronic components 27. The substrate 25 is, for example, a printed circuit board accommodated in the housing 10. The BGA 26 is an example of the electronic component. The BGA 26 and electronic components 27 are mounted on the substrate 25.

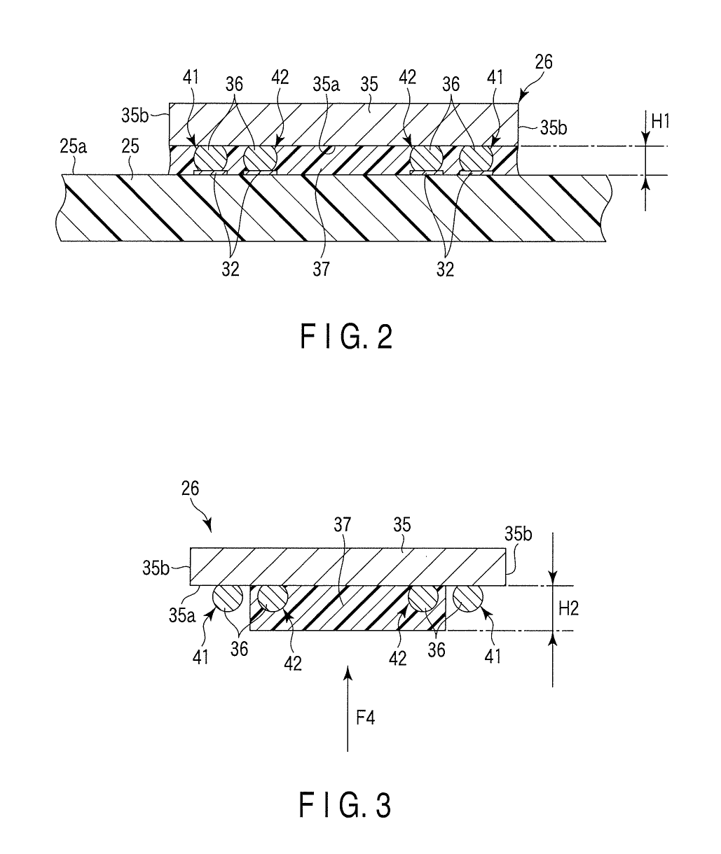

FIG. 2 is an exemplary enlarged sectional view showing the substrate 25 and BGA 26. As shown in FIG. 2, a plurality of pads 32 are provided on a surface 25a of the substrate 25. The pads 32 are arranged in a matrix, for example.

The BGA 26 comprises a plurality of terminals 36 and a resin 37. A component body 35 is an LSI accommodated in, for example, a rectangular case. The component body 35 is not limited to this and may alternatively be an exposed LSI or the like. A bottom surface 35a of the component body 35 faces the surface 25a of the substrate 25. Joint height H1 between the substrate 25 and component body 35 is, for example, 0.08±0.01 mm.

Each of the terminals 36 is, for example, a solder ball. Each terminal 36 is not limited to this and may alternatively be a pin-like lead wire or terminal of any other suitable shape. Corresponding to the pads 32, individually, the terminals 36 are arranged in a matrix on the bottom surface 35a of the component body 35. The terminals 36 are soldered to the pads 32, individually. In this way, the BGA 26 is mounted on the substrate 25.

The resin 37 is, for example, thermosetting epoxy resin doped with a flux. Alternatively, the resin 37 may be acrylic resin. Although an organic acid is used for the flux by way of example, it may be replaced with another substance, such as halogen. Doped with the flux, the resin 37 has a function to remove an oxide film when it is hot.

The resin 37 is introduced between the component body 35 and substrate 25. The resin 37 is cured and serves to strengthen the solder bond between the BGA 26 and substrate 25 by firmly securing the BGA 26 to the substrate 25.

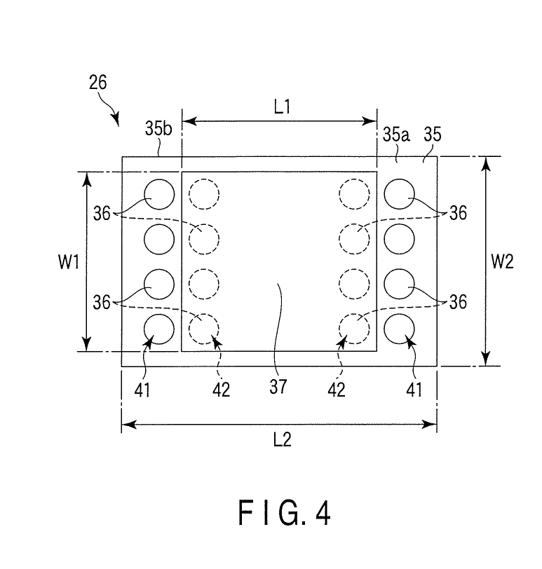

The following is a description of an example of a method for manufacturing the portable computer 1. FIG. 3 is an exemplary sectional view showing the BGA 26 to be mounted. FIG. 4 is an exemplary plan view of the BGA 26 to be mounted taken in the direction of arrow F4 of FIG. 3.

As shown in FIG. 3, the resin 37 is applied in a rectangular shape to the bottom surface 35a of the component body 35 by, for example, silk-screen printing. Before it is mounted, the resin 37, not yet thermally cured, is soft.

Thickness H2 of the resin 37 to be mounted is greater than joint height H1 shown in FIG. 2 and is, for example, 0.154 mm. As shown in FIG. 4, length L1 and width W1 of the resin 37 to be mounted are, for example, 20 mm and 16 mm, respectively. Length L2 of the component body 35 is greater than length L1 of the resin 37 and is, for example, 26±0.03 mm. Width W2 of the component body 35 is greater than width W1 of the resin 37 and is, for example, 21±0.03 mm. Thus, a capacity between the component body 35 and substrate 25 with a maximum tolerance is substantially equal to the volume of the resin 37 to be mounted.

The terminals 36 constitute a pair of first terminal portions 41 and a pair of second terminal portions 42. Each first terminal portion 41 comprises those terminals 36 which are arranged along an outer periphery 35b of the component body 35. Each second terminal portion 42 comprises those terminals 36 which are located inside its corresponding first terminal portion 41 with respect to the component body 35.

As shown in FIG. 4, the second terminal portions 42 are covered by the resin 37. In contrast, the first terminal portions 41 are exposed by virtue of not being covered by the resin 37. The second terminal portions 42 may alternatively be partially exposed.

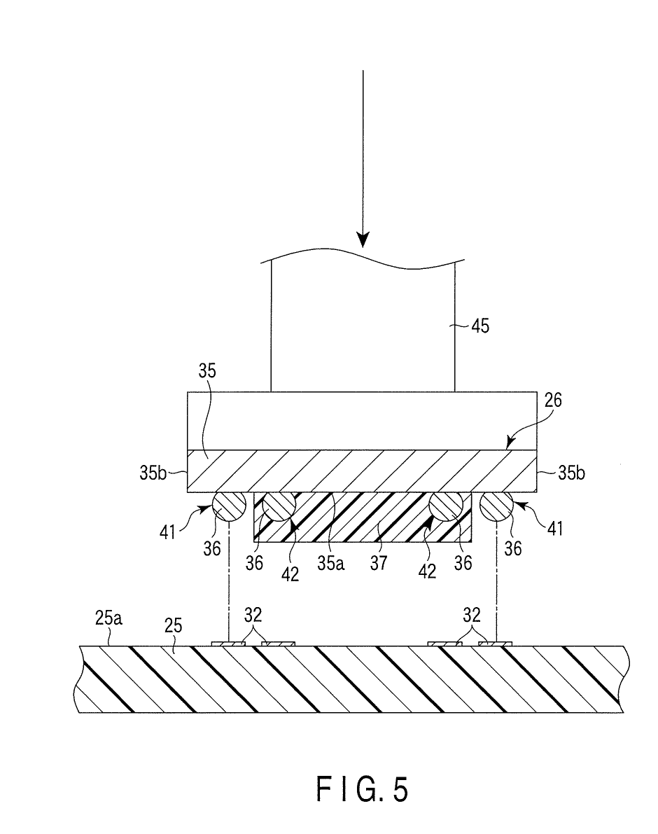

FIG. 5 is an exemplary sectional view schematically showing how the BGA 26 is put on the substrate 25. First, the BGA 26 to be mounted is held by a loading device 45 as it is moved onto the substrate 25, as shown in FIG. 5. The loading device 45 is a machine tool that serves to move and mount the BGA 26. The loading device 45 puts the BGA 26 on the surface 25a of the substrate 25 so that the terminals 36 correspond to the pads 32, individually.

Then, the loading device 45 heats the BGA 26 as it presses the BGA 26 toward the substrate 25, as indicated by an arrow in FIG. 5. The resin 37 becomes soft and fluid when it is heated to, for example, 150° C. Thus, the resin 37 is caused to flow by pressure from the loading device 45 or the weight of the component body 35.

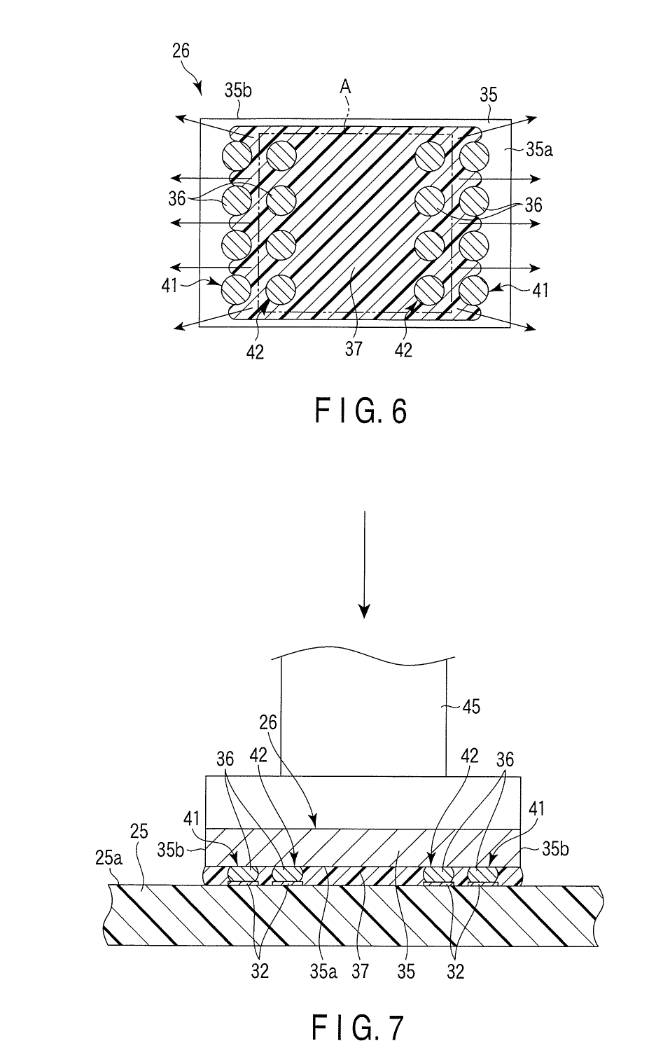

FIG. 6 is an exemplary sectional view schematically showing how the resin 37 is caused to flow by pressure. The resin 37 spreads outward, as indicated by arrows in FIG. 6, from position A where it has been applied before mounting, as indicated by a two-dot chain line. When the resin 37 contacts the terminals 36 in the first terminal portions 41, it flows so as to cover the terminals 36.

As the hot resin 37 spreads in this manner, it produces a gas. Since the flux in the resin 37 causes a redox reaction at the terminals 36, moreover, water vapor is produced by the terminals 36 and pads 32 in contact with the resin 37. The water vapor is an example of the gas. In addition, the hot substrate 25 produces water vapor. These gases exist between the substrate 25 and BGA 26.

Since the resin 37 spreads outward, it forces out the gas from itself and the water vapor from the substrate 25 through a gap between the BGA 26 and substrate 25. Since the resin 37 flows along the terminals 36, moreover, it forces out the water vapor from the terminals 36 and pads 32 through the gap between the BGA 26 and substrate 25.

FIG. 7 is a sectional view schematically showing how the BGA 26 is pressed against the substrate 25. As shown in FIG. 7, the loading device 45 presses the BGA 26 so that the terminals 36 contact the pads 32. The resin 37 between the terminals 36 and pads 32 flows so that the terminals 36 abut their corresponding pads 32.

When the terminals 36 contact the pads 32, the resin 37 reaches the outer periphery 35b of the component body 35. In other words, the resin 37 is introduced between the BGA 26 and substrate 25. The resin 37 is collected between the BGA 26 and substrate 25 and kept from overflowing by, for example, surface tension.

The loading device 45 further heats the BGA 26 with the terminals 36 in contact with the pads 32. The resin 37 starts to be thermally cured when it is heated to, for example, 200° C. If the terminals 36, which are solder balls, are melted, moreover, they are solder-bonded to the pads 32.

If the terminals 36 are solder-bonded, the loading device 45 is disengaged from the BGA 26. Thereupon, pressure from the loading device 45 is removed, so that the resin 37, having been projected from the gap between the BGA 26 and substrate 25, returns to the gap. In this way, the BGA 26 is mounted on the substrate 25, as shown in FIG. 2.

According to the portable computer 1 constructed in this manner and its manufacturing method, the resin 37 flows to force out the water vapors or gases from the gap between the BGA 26 and substrate 25 as the BGA 26 is mounted. Thus, air bubbles are prevented from being formed within the thermally cured resin 37.

The first terminal portions 41 located near the outer periphery 35b of the component body 35 are more susceptible to load than the second terminal portions 42. Since water vapor produced by the terminals 36 in the first terminal portions 41 is forced out by the flowing resin 37, it is prevented from contacting the terminals 36 of the first terminal portions 41 and thereby forming air bubbles. Thus, the contact between the terminals 36 of the BGA 26 and the pads 32 of the substrate 25 is strongly reinforced, so that the bonding reliability of the BGA 26 is improved.

When the BGA 26 is mounted, the resin 37 is collected in the gap between the BGA 26 and substrate 25 and does not flow out. Thus, the overflowed resin 37 is prevented from trapping air and thereby forming air bubbles therein.

Further, the solder-bonding of the BGA 26 and filling of the resin 37 are performed in one process. Thus, the number of processes for mounting the BGA 26 is reduced, so that the manufacturing cost of the portable computer 1 is reduced.

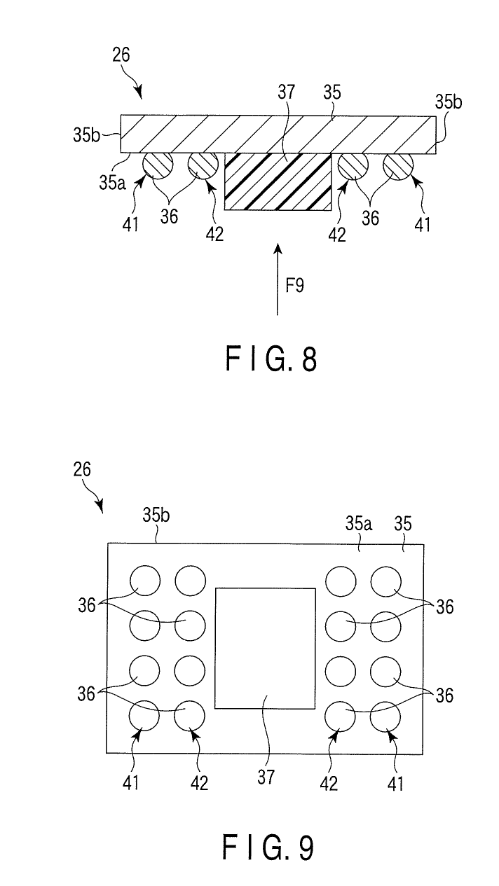

A second embodiment will now be described with reference to FIGS. 8 and 9. Like reference numbers are used to designate those constituent parts which have the same functions as their counterparts in the portable computer 1 of the first embodiment, and a description of those parts is omitted.

FIG. 8 is an exemplary sectional view showing a BGA 26 according to the second embodiment to be mounted. FIG. 9 is an exemplary plan view of the BGA 26 taken in the direction of arrow F9 of FIG. 8. In the BGA 26, as shown in FIG. 8, a resin 37 to be mounted is located inside second terminal portions 42 with respect to a component body 35. Therefore, all terminals 36 are exposed by virtue of not being covered by the resin 37. As in the first embodiment, the volume of the resin 37 to be mounted is substantially equal to a capacity between the component body 35 and substrate 25 with a maximum tolerance.

In mounting the BGA 26 constructed in this manner, the loading device 45 heats the BGA 26 as it presses the BGA 26 toward the substrate 25, as in the first embodiment. The resin 37 spreads outward from a position where it has been before mounting.

When the resin 37 contacts the terminals 36 in the second terminal portions 42, it flows so as to cover the terminals 36. In doing this, the resin 37 flows along the terminals 36 of the second terminal portions 42 and forces out water vapor produced by the terminals 36 and pads 32 through a gap between the BGA 26 and substrate 25. The resin 37 contacts the terminals 36 of first terminal portions 41 after having covered the second terminal portions 42.

According to a portable computer 1 constructed in this manner and its manufacturing method, the resin 37 forces out a gas produced by all the terminals 36 through the gap between the BGA 26 and substrate 25. Thus, formation of air bubbles is suppressed, so that the bonding reliability of the BGA 26 is further improved.

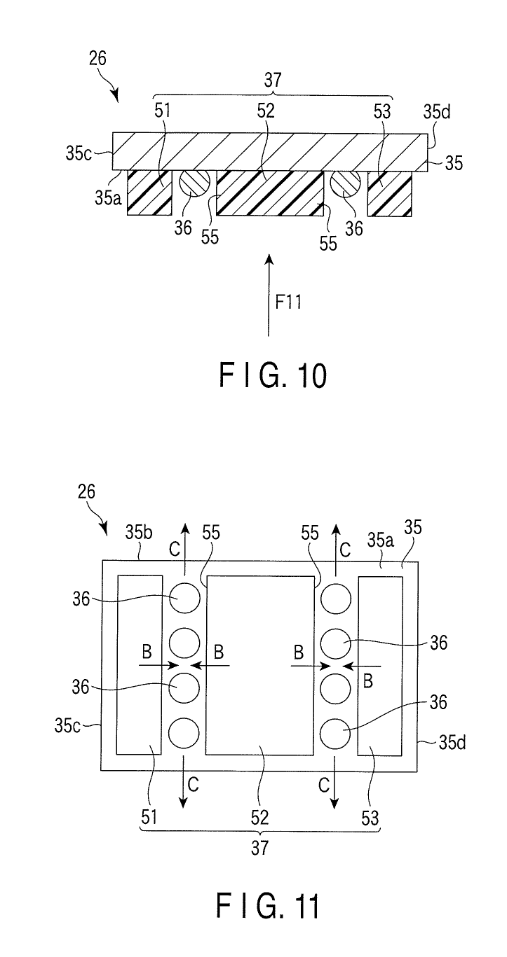

A third embodiment will now be described with reference to FIGS. 10 and 11. Like reference numbers are used to designate those constituent parts which have the same functions as their counterparts in the portable computer 1 of the first embodiment, and a description of those parts is omitted.

FIG. 10 is an exemplary sectional view showing a BGA 26 according to the third embodiment to be mounted. FIG. 11 is an exemplary plan view of the BGA 26 taken in the direction of arrow F11 of FIG. 10. As shown in FIG. 10, a resin 37 is divided into first portion 51, second portion 52 and third portion 53 and applied to a bottom surface 35a of a component body 35. A plurality of terminals 36 of the BGA 26 are arranged in two rows.

The first portion 51 is located between one end portion 35c of the component body 35 and the terminals 36. The second portion 52 is located inside the two rows of the terminals 36. The third portion 53 is located between the other end portion 35d of the component body 35 and the terminals 36.

As shown in FIG. 11, a pair of grooves 55 are formed between the first portion 51 and second portion 52 and between the second portion 52 and third portion 53, individually. The grooves 55 are an example of the space opening to the outer periphery of the electronic component and individually open to the outer periphery of the BGA 26. The terminals 36 are located in the grooves 55 and exposed by virtue of not being covered by the resin 37.

In mounting the BGA 26 constructed in this manner, the loading device 45 heats the BGA 26 as it presses the BGA 26 toward the substrate 25, as in the first embodiment. The first to third portions 51 to 53 spread outward and flow into the grooves 55, as indicated by arrows B in FIG. 11.

As the fluid first to third portions 51 to 53 flow into the grooves 55, air in the grooves 55 and water vapor produced by the terminals 36 and pads 32 are forced out of the grooves 55, as indicated by arrows C in FIG. 11. As the first to third portions 51 to 53 flowing into the grooves 55 are joined together, the resin 37 is introduced between the BGA 26 and substrate 25.

According to a portable computer 1 constructed in this manner and its manufacturing method, the first to third portions 51 to 53 force out air and gas from the grooves 55. Thus, formation of air bubbles is suppressed, so that the bonding reliability of the BGA 26 is improved.

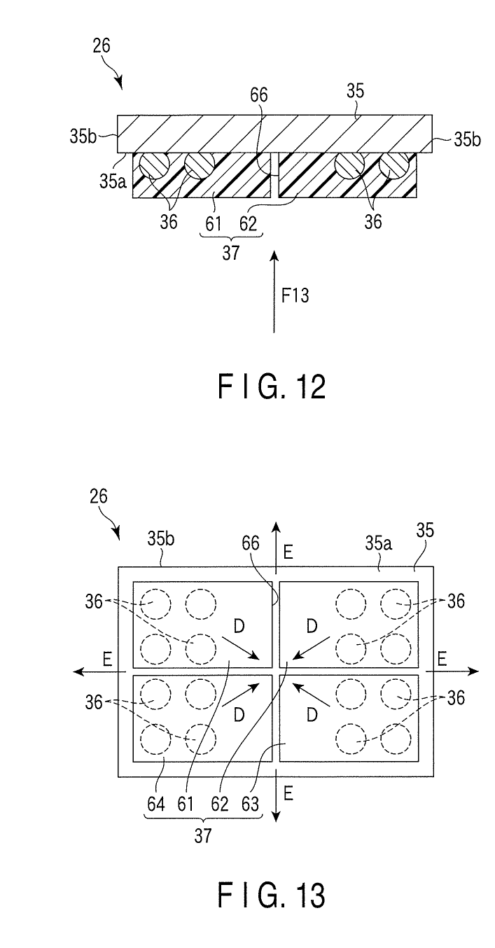

A fourth embodiment will now be described with reference to FIGS. 12 and 13. Like reference numbers are used to designate those constituent parts which have the same functions as their counterparts in the portable computer 1 of the first embodiment, and a description of those parts is omitted.

FIG. 12 is an exemplary sectional view showing a BGA 26 according to the fourth embodiment to be mounted. FIG. 13 is an exemplary plan view of the BGA 26 taken in the direction of arrow F13 of FIG. 12. As shown in FIG. 13, a resin 37 is divided into first portion 61, second portion 62, third portion 63 and fourth portions 64 and applied to a bottom surface 35a of a component body 35. The first to fourth portions 61 to 64 are individually arranged inside an outer periphery 35b of the component body 35. A plurality of terminals 36 are covered by the first to fourth portions 61 to 64, individually.

A cruciform groove 66 is formed between the first to fourth portions 61 to 64. The groove 66 separate the first portion 61 from the second portion 62; the second portion 62 from the third portion 63, the third portion 63 from the fourth portion 64, and the fourth portion 64 from the first portion 61. The groove 66 is an example of the space opening to the outer periphery of the electronic component and opens to the outer periphery of the BGA 26.

In mounting the BGA 26 constructed in this manner, the loading device 45 heats the BGA 26 as it presses the BGA 26 toward the substrate 25, as in the first embodiment. The first to fourth portions 61 to 64 spread outward and flow into the groove 66, as indicated by arrows D in FIG. 13.

As the fluid first to fourth portions 61 to 64 flow into the groove 66, air in the groove 66 is forced out of the groove 66, as indicated by arrows E in FIG. 13. As the first to fourth portions 61 to 64 flowing into the groove 66 are joined together, the resin 37 is introduced between the BGA 26 and substrate 25.

According to a portable computer 1 constructed in this manner and its manufacturing method, the first to fourth portions 61 to 64 force out air from the groove 66. Thus, formation of air bubbles is suppressed, so that the bonding reliability of the BGA 26 is improved.

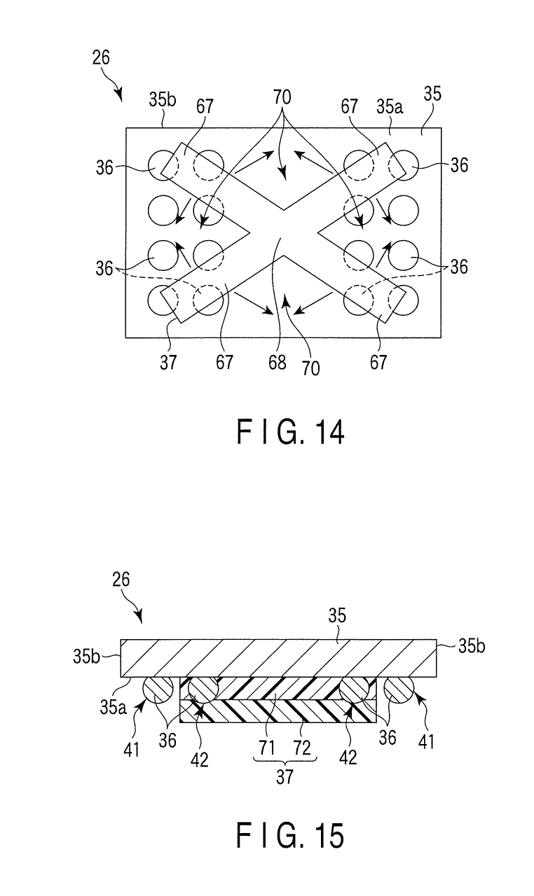

A fifth embodiment will now be described with reference to FIG. 14. Like reference numbers are used to designate those constituent parts which have the same functions as their counterparts in the portable computer 1 of the first embodiment, and a description of those parts is omitted.

FIG. 14 is an exemplary plan view showing a BGA 26 according to the fifth embodiment to be mounted. As shown in FIG. 14, a resin 37 is X-shaped and is applied to a component body 35. In other words, the resin 37 is shaped differently from the rectangular component body 35. The resin 37 is located inside an outer periphery 35b of the component body 35.

The resin 37 comprises a central portion 68 and four extending portions 69 individually extending from the central portion 68. The central portion 68 is located substantially in the center of a bottom surface 35a of the component body 35. The extending portions 69 individually partially cover a plurality of terminals 36.

Four spaces 70 are individually defined between the four extending portions 69. The spaces 70 are an example of the space opening to the outer periphery of the electronic component and individually open to the outer periphery of the BGA 26.

In mounting the BGA 26 constructed in this manner, the loading device 45 heats the BGA 26 as it presses the BGA 26 toward the substrate 25, as in the first embodiment. The four extending portions 69 spread outward and flow toward one another, as indicated by arrows in FIG. 14. Thus, air in the spaces 70 is forced out.

According to a portable computer 1 constructed in this manner and its manufacturing method, the four extending portions 69 force out air between them. Thus, formation of air bubbles is suppressed, so that the bonding reliability of the BGA 26 is improved.

Since the resin 37 is shaped differently from the rectangular component body 35, moreover, the angle at which the BGA 26 is mounted on the substrate 25 and the flow of the resin 37 are easily adjusted. Thus, the resin 37 is uniformly filled between the substrate 25 and BGA 26.

A sixth embodiment will now be described with reference to FIG. 15. Like reference numbers are used to designate those constituent parts which have the same functions as their counterparts in the portable computer 1 of the first embodiment, and a description of those parts is omitted.

FIG. 15 is an exemplary sectional view showing a BGA 26 according to the sixth embodiment to be mounted. As shown in FIG. 15, a resin 37 comprises first layer 71 and second layer 72. The first layer 71 is applied to a bottom surface 35a of a component body 35. The second layer 72 is laminated to the first layer 71 and contacts the substrate 25 and pads 32 when the BGA 26 is mounted.

The first layer 71 consists mainly of a resin that is higher in the rate of filler dispersion than the second layer 72 and has flux activity less than that of the second layer 72. In other words, the second layer 72 consists mainly of a resin that is lower in the rate of filler dispersion than the first layer 71 and has flux activity higher than that of the first layer 71. The flux activity is adjusted by, for example, the type of the resin or the amount of flux therein.

According to a portable computer 1 constructed in this manner and its manufacturing method, the second layer 72 that contacts the substrate 25 and pads 32 consists mainly of the resin with the low rate of filler dispersion. Thus, the bond between the BGA 26 and substrate 25 is satisfactory. Further, the resin of the second layer 72 has high flux activity. Thus, electrical contact between terminals 36 and the pads 32 is satisfactory.

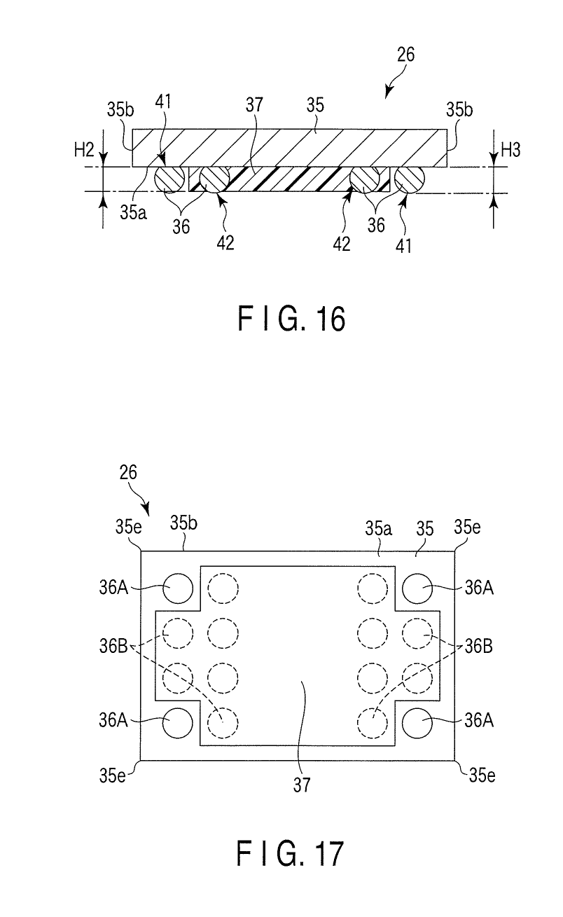

A seventh embodiment will now be described with reference to FIG. 16. Like reference numbers are used to designate those constituent parts which have the same functions as their counterparts in the portable computer 1 of the first embodiment, and a description of those parts is omitted.

FIG. 16 is an exemplary sectional view showing a BGA 26 according to the seventh embodiment to be mounted. As shown in FIG. 16, a resin 37 to be mounted has thickness H2 of, for example, 0.09 mm. Distance H3 from a bottom surface 35a of a component body 35 to the tip of each of terminals 36 to be mounted is, for example, 0.10 mm, which is greater than thickness H2 of the resin 37. Thus, the respective tip portions of the terminals 36 project from the resin 37.

In mounting the BGA 26 constructed in this manner, the loading device 45 puts the BGA 26 on the surface 25a of the substrate 25, as in the first embodiment. Since length H3 of each terminal 36 is greater than thickness H2 of the resin 37, the terminals 36 contact the pads 32 earlier than the resin 37. With the terminals 36 abutting the pads 32, the loading device 45 heats the BGA 26 as it presses the BGA 26 toward the substrate 25. The resin 37 thus heated and softened forces out air between the resin 37 and substrate 25 as it adheres to the surface of the substrate 25 and spreads outward.

As the terminals 36, solder balls, are melted, moreover, the joint height between the substrate 25 and component body 35 is reduced. The joint height between the substrate 25 and component body 35 is, for example, 0.08 mm, which is smaller than thickness H2 of the resin 37 to be mounted. Thus, the resin 37 is introduced between the BGA 26 and substrate 25, as shown in FIG. 2.

According to a portable computer 1 constructed in this manner and its manufacturing method, the terminals 36 contact the pads 32 earlier than the resin 37. Accordingly, it is prevented that the resin remains between the terminals 36 and pads 32, thereby preventing insufficient solder-bonding between them.

An eighth embodiment will now be described with reference to FIG. 17. Like reference numbers are used to designate those constituent parts which have the same functions as their counterparts in the portable computer 1 of the first embodiment, and a description of those parts is omitted.

FIG. 17 is an exemplary plan view showing a BGA 26 according to the eighth embodiment to be mounted. As shown in FIG. 17, the BGA 26 comprises four terminals 36A, which are located closest to four corner portions 35e of a component body 35, and a plurality of other terminals 36B. The four terminals 36A are individually exposed by virtue of not being covered by a resin 37. The other terminals 36B are covered by the resin 37.

In mounting the BGA 26 constructed in this manner, the loading device 45 moves the BGA 26 onto the substrate 25. The loading device 45 aligns the BGA 26 by detecting the four terminals 36A by means of a camera. In other words, the exposed terminals 36A function as marks for recognizing the position of the BGA 26.

The BGA 26 moved by the loading device 45 is put on the surface 25a of the substrate 25 and is heated as it is pressed against the substrate 25. The resin 37 softened by heating spreads outward and flows so as to cover the four terminals 36A.

According to a portable computer 1 constructed in this manner and its manufacturing method, the four terminals 36A near the corner portions 35e of the component body 35 function as recognition marks for aligning the BGA 26. Thus, a separate process for providing the BGA 26 with recognition marks is omitted, so that the productivity in manufacturing the portable computer 1 is improved.

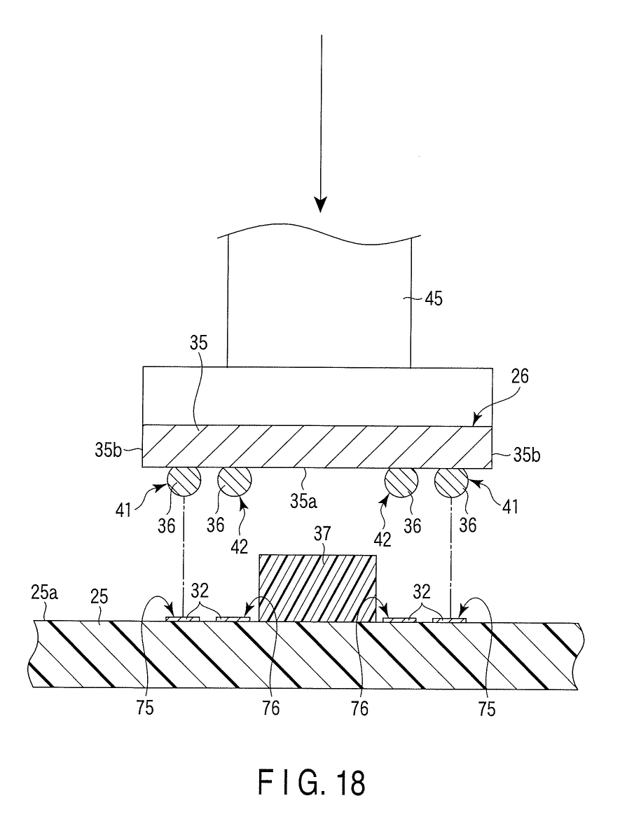

A ninth embodiment will now be described with reference to FIG. 18. Like reference numbers are used to designate those constituent parts which have the same functions as their counterparts in the portable computer 1 of the first embodiment, and a description of those parts is omitted.

FIG. 18 is an exemplary sectional view schematically showing how a BGA 26 according to the ninth embodiment is put on the substrate 25. As shown in FIG. 18, a resin 37 of the ninth embodiment is applied to the surface 25a of the substrate 25, not to the component body 35.

A plurality of pads 32 constitute a pair of first pad portions 75 corresponding to a pair of first terminal portions 41 and a pair of second pad portions 76 corresponding to a pair of second terminal portions 42. The resin 37 is located inside the second pad portions 76.

In mounting the BGA 26 constructed in this manner, the loading device 45 heats the BGA 26 as it presses the BGA 26 toward the substrate 25, as in the first embodiment. The resin 37 is softened by being heated through the BGA 26 by the loading device 45. The softened resin 37 spreads outward, as in the first embodiment. The same effect as that of the first embodiment is obtained even if the resin 37 is applied to the surface 25a of the substrate 25 in this manner.

A tenth embodiment will now be described with reference to FIG. 2. Like reference numbers are used to designate those constituent parts which have the same functions as their counterparts in the portable computer 1 of the first embodiment, and a description of those parts is omitted.

In the tenth embodiment, silver powder, for example, is mixed in the resin 37. The silver powder is an example of the electrical conductor powder. The conductor powder is not limited to silver powder and may alternatively be another metal powder, such as copper powder, or other electrically conductive powder. The amount of silver powder to be mixed into the resin 37 is adjusted to prevent shorting between adjacent terminals 36.

In mounting a BGA 26 constructed in this manner, the loading device 45 heats the BGA 26 as it presses the BGA 26 toward the substrate 25, as in the first embodiment. If the resin 37 remains between the terminals 36 and pads 32 even though the BGA 26 is pressed, the terminals 36 and pads 32 are electrically connected by the silver powder in the resin 37.

According to a portable computer 1 constructed in this manner and its manufacturing method, the terminals 36 and pads 32 are electrically connected even if the resin 37 remains between them. Thus, the BGA 26 is reliably mounted on the substrate 25.

Although the BGA 26 is used as an example of the electronic component in each of the embodiments described herein, the present invention is not limited to this. Various other electronic components, e.g., a PGA, CSP, QFN, LGA, or flip chip, may be used instead.

Further, the thermosetting resin that serves to remove an oxide film when it is hot is not limited to a flux-doped resin. For example, it may be a resin that can remove an oxide film on a metal surface by reducing oxygen from the oxide film by means of an intermediate product during thermal curing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for an electronic apparatus, which comprises a housing, a substrate accommodated in the housing, a plurality of pads on a surface of the substrate, and an electronic component, which comprises a component body comprising a bottom surface opposed to the surface of the substrate, a plurality of terminals arranged on the bottom surface of the component body, and a thermosetting resin disposed on the bottom surface of the component body and configured to remove an oxide film when heated, and is mounted on the substrate, the method comprising:
putting the electronic component on the surface of the substrate;
heating the electronic component on the substrate, thereby softening the resin;
causing the softened resin to flow, thereby forcing out a gas between the electronic component and the substrate and filling the resin between the electronic component and the substrate; and
further heating the electronic component, thereby solder-bonding the terminals and the pads to one another and curing the resin between the electronic component and the substrate.

2. The electronic apparatus manufacturing method of claim 1, wherein those terminals which are arranged along an outer periphery of the component body constitutes a first terminal portion, those terminals which are located inside the first terminal portion with respect to the component body constitute a second terminal portion, and the resin to be softened allows the first terminal portion to be exposed and covers the second terminal portion.

3. The electronic apparatus manufacturing method of claim 1, wherein the resin to be softened is located inside the terminals with respect to the component body.

4. The electronic apparatus manufacturing method of claim 1, wherein the resin defines a space opening to the outer periphery of the electronic component before the electronic component is put in place.

5. The electronic apparatus manufacturing method of claim 1, wherein the resin to be softened comprises a first layer applied to the bottom surface of the component body and a second layer which is laminated to the first layer and is lower in the rate of filler dispersion than the first layer.

6. The electronic apparatus manufacturing method of claim 1, wherein respective tip portions of the terminals project from the resin to be softened.

7. The electronic apparatus manufacturing method of claim 1, wherein those terminals which are located closest to corner portions of the component body are exposed before the resin is softened, and the electronic component is aligned by detecting the exposed terminals as the electronic component is put on the substrate.

8. The electronic apparatus manufacturing method of claim 1, wherein electrical conductor powder is mixed in the resin.

9. An electronic component comprising:
a component body comprising a bottom surface;
a plurality of terminals arranged on the bottom surface of the component body; and
a thermosetting resin disposed on the bottom surface of the component body and configured to remove an oxide film when heated.

10. The electronic component of claim 9, wherein those terminals which are arranged along an outer periphery of the component body constitutes a first terminal portion, those terminals which are located inside the first terminal portion with respect to the component body constitute a second terminal portion, and the resin allows the first terminal portion to be exposed and covers the second terminal portion.

11. The electronic component of claim 9, wherein the resin is located inside the terminals with respect to the component body, and the terminals are exposed.

12. The electronic component of claim 9, wherein the resin defines a space opening to the outer periphery of the electronic component.

13. The electronic component of claim 9, wherein the resin comprises a first layer applied to the bottom surface of the component body and a second layer which is laminated to the first layer and is lower in the rate of filler dispersion than the first layer.

14. The electronic component of claim 9, wherein respective tip portions of the terminals project from the resin.

15. The electronic component of claim 9, wherein electrical conductor powder is mixed in the resin.

16. An electronic apparatus comprising:
a housing;
a substrate accommodated in the housing;
a pad on a surface of the substrate;
a component body comprising a bottom surface opposed to the surface of the substrate,
a terminal disposed on the bottom surface of the component body and electrically connected to the pad; and
a thermosetting resin introduced between the substrate and the component body and configured to remove an oxide film when heated.
